(19) United States
(12) Patent Application Publication
(10) Pub. No.: US 2025/0274080 A1
(43) Pub. Date: Aug. 28, 2025

(54) DUAL-PASSBAND DOHERTY POWER AMPLIFIER

(71) Applicant: City University of Hong Kong, Kowloon (HK)

(72) Inventors: Wing Shing Chan, Kowloon (HK); Liheng Zhou, Jiasngsu (CN); Xinyu Zhou, Tai Po (HK)

(21) Appl. No.: 18/584,271

(22) Filed: Feb. 22, 2024

(51) Int. Cl. H03F 1/02; H03F 1/56; H03F 3/24

(52) U.S. Cl. CPC H03F 1/0288; H03F 1/565; H03F 3/245

(57) ABSTRACT

A Doherty power amplifier which contains an input, an output, a main power amplification device connected between the input and the output, an auxiliary power amplification device connected between the input and the output and arranged in parallel with the main power amplification device, a main side OMN connected between the main power amplification device and the output, and an auxiliary side OMN connected between the auxiliary power amplification device and the output. The main side and auxiliary side OMNs each include a first shunted T junction, where the first shunted T junctions facilitate creation of multiple transmission zeros (TZ) as well as impedance conversion. The compact and dual-band DPAs can operate over two wide passbands, which is realized by the multiple TZs in an all-pass response.

### FIELD OF INVENTION

This invention relates to power amplifiers and in particular to Doherty power amplifiers used in RF (Radio Frequency)/Microwave/Wireless systems.

### BACKGROUND OF INVENTION

Modern communication systems engineers are continuously in the pursuit of high data rate, using spectrally-efficient digital modulation schemes. These signals have rapidly varying envelopes with a wide dynamic range, leading to a large peak-to-average-power ratio (PAPR) [1], which requires high efficiency at output back-off (OBO). Doherty power amplifiers (DPAs) have been widely adopted in base station transmitters for efficiency enhancement at OBO [2]-[3], due to its better linearity and relatively simple circuitry.

A wideband DPA is highly desirable to reduce hardware investment and electrical power costs [4]-[8]. However, external interference can enter back into this transmitter through the antenna over a wide frequency range [9]. In contrast, a dual-band DPA can realize a larger frequency ratio with outputs concentrated into two target bands. Out-of-band spurious are effectively suppressed, thus mitigating intermodulation distortion. A multi-section λ/4 impedance transformer was used as an impedance inverting and transforming network with up to four operating frequencies [10]. In [11] and [12], λ/4 impedance transformers were replaced by T-type networks to construct dual-band input power splitter, output matching networks (OMN) and offset line. Short- and open-circuit stub-loaded π-type networks were used for the impedance transformer and offset line to realize a dual-band DPA [13]. Harmonic-tuning stubs were added to the OMN [14] or post-matching network (PMN) [15] in order to increase efficiency. A 3-way dual-band DPA was presented based on a π-type OMN, which could absorb C_{ds} resulting in an increased bandwidth [16]. In [17], a generalized combining network with multi-solution was introduced as the output combiner of a dual-band DPA. It showed good performance at 9-dB OBO by only using a 2-way architecture. In [18], a multiband DPA was designed based on phase periodic matching networks, while reciprocal gate biases are used to further increase the number of operating bands, resulting in a dual-mode operation. Most reported dual-band works have only been able to operate at two frequency points or with a frequency span of just 100 MHz.

A filter is usually cascaded after the PA to suppress spurious harmonic produced by the transistor nonlinearities. Their integrated design reduces circuit size and cost. Furthermore, harmonic signals are blocked to reduce system interference, which can also be used for waveform engineering to enhance efficiency and output power [19]. For a filtering PA design, the filter is modified to give an asymmetrical filtering impedance conversion which acts as the PA's OMN. However, this method is difficult to realize in a DPA due to the phase difference between the carrier and peaking path. Instead, the filtering transformer can only be placed after the summing node as a PMN, but results in a large size [20]. In [21], a dual-band filtering DPA is presented and the bandpass response is realized using a resonant combiner, but the frequency ratio is small and only works at two frequency points. Large frequency ratio no doubt will increase the design difficulty of OMNs because the load-pull results are significantly different in the two bands. A dual-band filtering DPA with wide bandwidth and frequency ratio greater than 2 has never been reported.

### REFERENCES

Each of the following references (and associated appendices and/or supplements) is expressly incorporated herein by reference in its entirety:
[1]P. Ramabadran et al., “A novel physical layer authentication with PAPR reduction based on channel and hardware frequency responses,” IEEE Trans. Circuits Syst. I, Reg. Papers, vol. 67, no. 2, pp. 526-539, February 2020.
[2]X. Zhou, W. S. Chan, T. Sharma, J. Xia, S. Chen, and W. Feng, “A Doherty power amplifier with extended high-efficiency range using three-port harmonic injection network,” IEEE Trans. Circuits Syst. I, Reg. Papers, vol. 69, no. 7, pp. 2756-2766, July 2022.
[3]X. Zhou, S. Chowdhury, R. P. Martinez, and B. Shankar, “Design of Ka-band Doherty power amplifier using 0.15 md GaN on SiC process based on novel complex load modulation,” in Proc. IEEE 8th Workshop Wide Bandgap Power Devices Appl. (WiPDA), Redondo Beach, CA, USA, November 2021, pp. 259-262.
[4]M. Li, J. Pang, Y. Li, and A. Zhu, “Bandwidth enhancement of Doherty power amplifier using modified load modulation network,” IEEE Trans. Circuits Syst. I, Reg. Papers, vol. 67, no. 6, pp. 1824-1834, June 2020.
[5]R.-J. Liu et al., “Highly efficient wideband GaN MMIC Doherty power amplifier considering the output capacitor influence of the peaking transistor in class-C operation,” IEEE Trans. Circuits Syst. I, Reg. Papers, vol. 69, no. 5, pp. 1932-1942, May 2022.
[6]S. Rafati, V. Nayyeri, and M. Soleimani, “A 100-W Doherty power amplifier with super-octave bandwidth,” IEEE Trans. Circuits Syst. II, Exp. Briefs, vol. 67, no. 6, pp. 1009-1013, June 2020.
[7]W. Shi et al., “Design and analysis of continuous-mode Doherty power amplifier with second harmonic control,” IEEE Trans. Circuits Syst. II, Exp. Briefs, vol. 68, no. 7, pp. 2247-2251, July 2021.
[8]W. Kong, J. Xia, X. Zhou, T. Zhang, W. Zhang, and X. Bao, “Band-width extension of three-way Doherty power amplifier with reactance compensation using parallel peaking amplifiers,” IEEE Access, vol. 9, pp. 91661-91669, 2021.
[9]S. Ahmed and M. Faulkner, “Mitigation of reverse intermodulation products at colocated base stations,” IEEE Trans. Circuits Syst. I, Reg. Papers, vol. 60, no. 6, pp. 1608-1620, June 2013.
[10]X. A. Nghiem, J. Guan, T. Hone, and R. Negra, “Design of con-current multiband Doherty power amplifiers for wireless applications,” IEEE Trans. Microw. Theory Techn., vol. 61, no. 12, pp. 4559-4568, December 2013.
[11]W. Chen et al., “Design and linearization of concurrent dual-band Doherty power amplifier with frequency-dependent power ranges,” IEEE Trans. Microw. Theory Techn., vol. 59, no. 10, pp. 2537-2546, October 2011.
[12]W. Chen, S. Zhang, Y. Liu, Y Liu, and F. M. Ghannouchi, “Aconcurrent dual-band uneven Doherty power amplifier with frequency-dependent input power division,” IEEE Trans. Circuits Syst. I, Reg. Papers, vol. 61, no. 2, pp. 552-561, February 2014.
[13]K. Rawat and F. M. Ghannouchi, “Design methodology for dual-band Doherty power amplifier with performance enhancement using dual-band offset lines,” IEEE Trans. Ind. Electron., vol. 59, no. 12, pp. 4831-4842, December 2012.
[14]P. Saad, P. Colantonio, L. Piazzon, F. Giannini, K. Andersson, and C. Fager, “Design of a concurrent dual-band 1.8-2.4-GHz GaN-HEMT Doherty power amplifier,” IEEE Trans. Microw. Theory Techn., vol. 60, no. 6, pp. 1840-1849, June 2012.
[15]Z. Yang, M. Li, Y. Yao, Z. Dai, T. Li, and Y. Jin, “Design of concurrent dual-band continuous class-J mode Doherty power amplifier with precise impedance terminations,” IEEE Microw. Wireless Compon. Lett., vol. 29, no. 5, pp. 348-350, May 2019.
[16]M. Liu, X. Fang, H. Huang, and S. Boumaiza, “Dual-band 3-way Doherty power amplifier with extended back-off power and bandwidth,” IEEE Trans. Circuits Syst. II, Exp. Briefs, vol. 67, no. 2, pp. 270-274, February 2020.
[17]H.-Y. Liu, C. Zhai, and K. M. Cheng, “Novel dual-band equal-cell Doherty amplifier design with extended power back-off range,” IEEE Trans. Microw. Theory Techn., vol. 68, no. 3, pp. 1012-1021, March 2020.
[18]J. Pang, Z. Dai, Y. Li, M. Li, and A. Zhu, “Multiband dual-mode Doherty power amplifier employing phase periodic matching network and reciprocal gate bias for 5G applications,” IEEE Trans. Microw. Theory Techn., vol. 68, no. 6, pp. 2382-2397, June 2020.
[19]Y. C. Li, Q.-C. Chen, Q. Xue, and J. Mou, “Filtering power ampli-fier with wide bandwidth using discriminating coupling,” IEEE Trans. Circuits Syst. I, Reg. Papers, vol. 66, no. 10, pp. 3822-3830, October 2019.
[20]J.-X. Xu and X. Y. Zhang, “Dual-channel dielectric resonator filter and its application to Doherty power amplifier for 5G massive MIMO sys-tem,” IEEE Trans. Microw. Theory Techn., vol. 66, no. 7, pp. 3297-3305, July 2018.
[21]H. Chen, J.-X. Xu, W. Chen, and X. Y. Zhang, “High-efficiency dual-band filtering Doherty power amplifier based on multi-function circuit,” IEEE Trans. Microw. Theory Techn., vol. 70, no. 5, pp. 2697-2709, May 2022.
[22]R. Gómez-García, L. Yang, J.-M. Munoz-Ferreras, and D. Psychogiou, “Single/multi-band coupled-multi-line filtering section and its applica-tion to RF diplexers, bandpass/bandstop filters, and filtering couplers,” IEEE Trans. Microw. Theory Techn., vol. 67, no. 10, pp. 3959-3972, October 2019.
[23]Q. Xue and J. Y. Jin, “Bandpass filters designed by transmission zero resonator pairs with proximity coupling,” IEEE Trans. Microw. Theory Techn., vol. 65, no. 11, pp. 4103-4110, November 2017.
[24]C. R. Chappidi, T. Sharma, and K. Sengupta, “Multi-port active load pulling for mm-wave 5G power amplifiers: Bandwidth, back-off effi-ciency, and VSWR tolerance,” IEEE Trans. Microw. Theory Techn., vol. 68, no. 7, pp. 2998-3016, July 2020.
[25]L.-H. Zhou, X. Y. Zhou, and W. S. Chan, “A compact and broadband Doherty power amplifier without post-matching network,” IEEE Trans. Circuits Syst. II, Exp. Briefs, vol. 70, no. 3, pp. 919-923, March 2023.
[26]H. M. Nemati, C. Fager, U. Gustavsson, R. Jos, and H. Zirath, “Design of varactor-based tunable matching networks for dynamic load modulation of high power amplifiers,” IEEE Trans. Microw. Theory Techn., vol. 57, no. 5, pp. 1110-1118, May 2009.

### SUMMARY OF INVENTION

Accordingly, the invention in one aspect provides a Doherty power amplifier which contains an input, an output, a main power amplification device connected between the input and the output, an auxiliary power amplification device connected between the input and the output and arranged in parallel with the main power amplification device, a main side OMN connected between the main power amplification device and the output, and an auxiliary side OMN connected between the auxiliary power amplification device and the output. The main side and auxiliary side OMNs each include a first shunted T junction, where the first shunted T junctions facilitate creation of multiple transmission zeros (TZ) as well as impedance conversion.

In some embodiments, the first shunted T junction of the main side OMN or the auxiliary side OMN facilitates generation of two TZs in a corresponding one of the main side and auxiliary side OMNs.

In some embodiments, the main side OMN further includes a shunted short-circuit stub, and a λ/4 transformer connected between the first shunted T junction and the shunted short-circuit stub.

In some embodiments, the auxiliary side OMN further includes a second shunted T junction, and a λ/4 transformer at least partially connected between the first and second shunted T junctions.

In some embodiments, the Doherty power amplifier further includes a stub-loaded power divider connected between the input, and the main and auxiliary power amplification devices.

In some embodiments, the Doherty power amplifier further includes a main side input impedance matching network (IMN) connected between the stub-loaded power divider and the main power amplification device, and an auxiliary side IMN connected between the stub-loaded power divider and the auxiliary power amplification device.

In some embodiments, the Doherty power amplifier further includes a phase compensation network (PCN) located in the auxiliary side IMN.

In some embodiments, the first shunted T junction is connected to a drain of a corresponding one of the main and auxiliary power amplification devices.

In some embodiments, input impedances of the main and auxiliary power amplification devices are complex impedances, and a load impedance of the Doherty power amplifier is a real impedance.

Embodiments of the invention thus provide compact and dual-band DPAs that can operate over two wide passbands, which is realized by multiple TZs in an all-pass response. Traditional filtering PAs are commonly based on cascaded impedance-conversion resonators which result in large size and cost. In embodiments of the invention, a novel filtering DPA is presented based on multiple loaded stubs, while the required impedance transformation in two wideband range can be realized by them. The short/open stub loaded stepped-impedance transformers act as the OMNs in both carrier and peaking paths. The shunted stubs not only generate TZs but also perform impedance conversion, simultaneously satisfying the load-pull requirements at both OBO and saturation. This is achieved over two wide frequency ranges. The combination between the OMNs in the two paths realizes a dual-passband response, even though the number of TZs at saturation is one less than that at OBO. The dual-band DPAs according to embodiments of the invention result in the size, loss and cost of circuit for base station transmitter to be significantly reduced in future wireless communication systems and it can be reproduced based on other transistors and operating frequency ranges.

### BRIEF DESCRIPTION OF FIGURES

The foregoing and further features of the present invention will be apparent from the following description of embodiments which are provided by way of example only in connection with the accompanying figures, of which:

FIG. 1 illustrates a load-modulation scheme in a dual-band DPA according to a first embodiment of the invention.

FIG. 2a shows a conventional dual-passband configuration using multiple resonators.

FIG. 2b shows another conventional dual-passband configuration using multiple TZs.

FIG. 3a shows load-pull simulation results for the carrier device in the DPA of FIG. 1 in the lower band. Solid: saturation, PAE>60%, Pₒᵤₜ>41 dBm. Dash: OBO, PAE>55%.

FIG. 3b shows load-pull simulation results for the carrier device in the DPA of FIG. 1 in the upper band. Solid: saturation, PAE>55%, Pₒᵤₜ>40.5 dBm. Dash: OBO, PAE>50%.

FIG. 4a illustrates an exemplary λ/4 impedance transformer and an exemplary 2-order stepped-impedance line (SIL).

FIG. 4b depicts real and imaginary parts of Zₜ, Z₂=26 Ω. θ₂=90° in the simulation of the λ/4 impedance transformer in FIG. 4a.

FIG. 5a shows real and imaginary parts of Z₂ₜ, θ₂=90° in the simulation of the 2-order SIL in FIG. 4a, when Z₁=22Ω, Z₂=26 Ω, θ₁=140°, f_{U}/f_{L}=1.91.

FIG. 5b shows real and imaginary parts of Z₂ₜ, θ₂=90° in the simulation of the 2-order SIL in FIG. 4a, when Z₁=24Ω, Z₂=28 Ω, θ₁=125°, f_{U}/f_{L}=2.

FIG. 6a depicts the structure of a carrier side OMN according to an embodiment of the invention.

FIG. 6b depicts the structure of a peaking side OMN according to an embodiment of the invention.

FIG. 7a depicts simulated input impedance of the OMN in FIG. 6a when Zᵢ, Z_{c1}=70 Ω, θ_{c1}=180°.

FIG. 7b depicts simulated input impedance of the OMN in FIG. 6a when Zᵢₙ, Z_{c2}=30Ω, B_{c2}=85°.

FIG. 8 depicts simulated input impedance of the OMN in FIG. 6a when Z_{inc}. Z_{c}=70 Ω, θ_{c34}=40°.

FIG. 9a depicts simulated input impedance of the OMN in FIG. 6a when adjusting Z_{incc} at f_{U}.

FIG. 9b depicts simulated input impedance of the OMN in FIG. 6a when adjusting Z_{incc} at f_{L}.

FIG. 9c depicts simulated input impedance of the OMN in FIG. 6a when adjusting Z_{incc} at f_{L}.

FIG. 9d depicts simulated input impedance of the OMN in FIG. 6a when adjusting TZ_{c2}.

FIG. 10a shows load-pull results for the peaking device; lower band: PAE>65%, Pₒᵤₜ>39.5 dBm; upper band: PAE>60%, Pₒᵤₜ>38.5 dBm.

FIG. 10b shows the λ/4 transformer with the T junction T2 in the OMN of FIG. 6b alone.

FIG. 10c shows the impedance conversion result of FIG. 10 (b).

FIG. 10d illustrates S parameters when Zₚ₁=35Ω, θₚ₁₃₌₈₀°, Zₚ=47Ω, θₚ₄₌₂₀°, θₚ₅=30°.

FIG. 11a shows how stub Opt is used to slightly tune the S₂₁ of OMN_{P}.

FIG. 11b shows the input impedance of Zₚₘ of T3.

FIG. 11c shows Zᵢₙ of OMN_{P}.

FIG. 11d shows S₂₁ of OMN_{P+} OMN_{C} at saturation.

FIG. 12a shows the block diagram of the OMNs in FIGS. 6a-6b at OBO, in which OL is the offset line.

FIG. 12b shows S₂₁ of the OBO path of the OMN_{C} of FIG. 6a.

FIG. 13a illustrates S₂₁ of OMN_{P}+OMN_{C} of FIGS. 6a-6b at OBO.

FIG. 13b illustrates Zpo of OMNP+OMNC of FIGS. 6a-6b at OBO.

FIG. 14a shows a stub-loaded power divider according to one embodiment of the invention for using in a DPA.

FIG. 14b shows the even-mode bisection in sub-circuits of the power divider of FIG. 14a.

FIG. 14c shows the odd-mode bisection in sub-circuits of the power divider of FIG. 14a.

FIG. 14d shows simulated S parameters of the power divider of FIG. 14a.

FIG. 15 is a schematic diagram of a dual-passband DPA according to one embodiment of the invention.

FIG. 16 shows small-signal responses from measurement and simulation of the DPA in FIG. 15.

FIG. 17a shows simulated large-signal responses of the DPA in FIG. 15, from 1.45 to 1.85 GHz.

FIG. 17b shows simulated large-signal responses of the DPA in FIG. 15, from 2.95 to 3.35 GHz.

FIG. 18a shows measured large-signal responses of the DPA in FIG. 15, from 1.35 to 1.75 GHz.

FIG. 18b shows measured large-signal responses of the DPA in FIG. 15, from 3.05 to 3.45 GHz.

FIG. 19 shows, for the DPA in FIG. 15, measured large-signal performance comparison versus frequency.

FIG. 20 shows simulated and measured output power versus frequency for the DPA in FIG. 15.

FIG. 21a shows measured ACLR at the frequencies of 1.35, 1.45, 1.55, 1.65 and 1.75 GHz.

FIG. 21b shows measured ACLR at the frequencies of 3.05, 3.15, 3.25, 3.35 and 3.45 GHz.

FIG. 22 is a table showing performance comparison of the DPA in FIG. 15 as compared to other conventional dual-band DPAs.

### DETAILED DESCRIPTION

FIG. 1 shows a load-modulation scheme of a dual-band Doherty power amplifier according to a first embodiment of the invention. It should be noted that there is no specific circuit implementation illustrated in FIG. 1, because there is more than one possible implementation for the DPA in FIG. 1, examples of which will be described in details later. There are two parallel amplifier paths in the DPA of FIG. 1, and two power amplification devices are located respectively on the two paths, as understood by those skilled in the art. In particular, in a carrier path there is a main power amplification device 20 that operates in class B mode, and in a peaking path there is an auxiliary power amplification device 22 that operates in class C mode. The two power amplification devices 20, 22 are illustrated as two voltage-controlled current sources in FIG. 1, but skilled persons will understand that in actual circuits the power amplification devices may include amplifier elements (e.g., transistors), a RF input, input impedance matching circuits, etc., all of which are not illustrated in FIG. 1.

The output of the main power amplification device 20 connects to a main side OMN which is the OMN_{C} 24 in the carrier path. Similarly, the output of the auxiliary power amplification device 22 connects to an auxiliary side OMN which is the OMN_{P} 28 in the peaking path. In FIG. 1, Z_{lcp/p} is the required load-pull impedance that will be realized by the OMN_{C} 24 and the OMN_{P} 28. The OMN_{C} 24 is required to simultaneously convert Z_{lpc} to a pure resistance R_{L} at OBO and 2R_{L} at saturation to satisfy load modulation. In one example, R_{L} is selected to be 35Ω. In comparison, OMN_{P} 28 works only at saturation because the peaking device (i.e., the auxiliary power amplification device 22) turns off at OBO. The output of the OMN_{C} 24 and the output of the OMN_{P} 28 are summed at a summing node 21 of the DPA, in order to produce a high impedance toward the auxiliary power amplification device 22 when it is off. The summing node 21 as understood by skilled person is at the location where a main amplifier current I_{C} from the main power amplification device 20 and an auxiliary amplifier current I_{P} from the auxiliary power amplification device 22 are combined. A PMN 26 after the summing node 21 converts. R_{L} to 50 Ω.

It should be emphasized that the DPA shown in FIG. 1 is a dual-band DPA that can operate over two wide passbands, which is realized by multiple TZs in an all-pass response. In exemplary implementations of the DPA that will be described in more details below, the OMNs in the carrier and peaking paths are realized by short/open stub loaded stepped-impedance transformers, and the stubs are shunted stubs. The shunted stubs not only generate TZs but also perform impedance conversion, simultaneously satisfying the load-pull requirements at both OBO and saturation. This is achieved over two wide frequency ranges. The combination between the OMNs in the two paths realizes a dual-passband response, even though the number of TZs at saturation is one less than that at OBO.

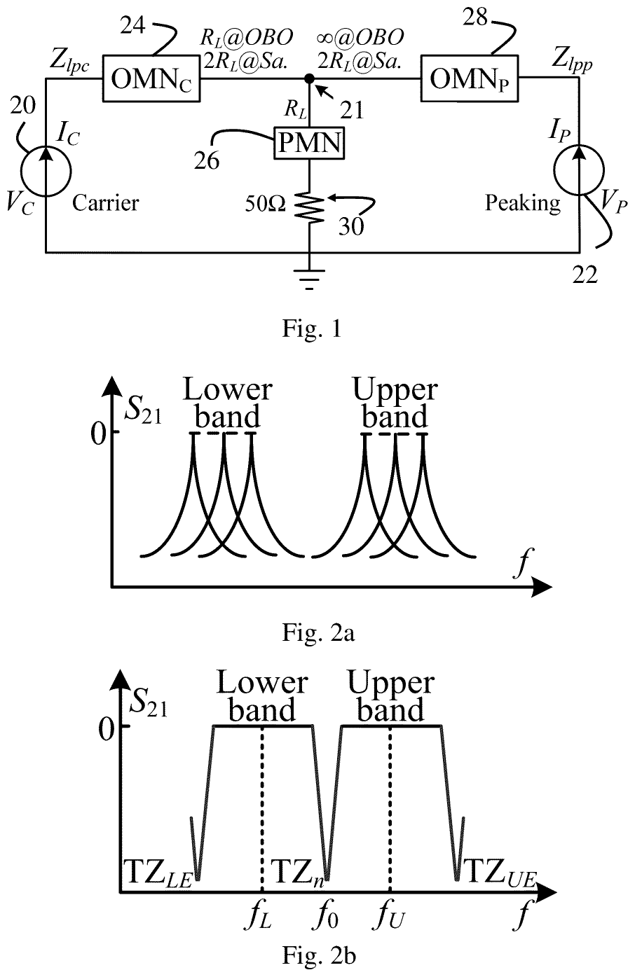

Before describing the detailed stricture of the exemplary implementations of the DPA in FIG. 1, a common, conventional method to construct dual passbands using multiple resonators as shown in FIG. 2a will be described briefly. The lower and upper bands in FIG. 2a come from fundamental and harmonic frequencies of cascaded resonators, respectively. If wide bandwidth is required, multiple resonators are necessary but at the cost of complex structures, high loss, in-band ripple and large size [22]. Another alternative method is to insert multiple TZs into an all-pass response, resulting in two flat, low-loss and wide passbands, as shown in FIG. 2b [23].

For convenience of expression, f_{L} and f_{U} stand for lower and upper bands, respectively, although they are also center frequencies. f₀ is defined as 2f₀=f_{L}+f_{U} and all electric lengths in the following figures correspond to f₀. It is well known that SIL is practically all-pass and with the impedance conversion capability, while shunted stubs are the most straightforward way to generate TZ. Therefore, their combination is a good candidate for the OMNs to achieve dual-passband response. However, it is easily overlooked that a shunted stub also affects the impedance conversion when used to realize TZs. Therefore, a stub-loaded stepped-impedance transformer needs a more elaborate design methodology to realize a dual-band OMN which will be analyzed below.

Different from traditional filtering PA which relies on cascaded resonators like that in FIG. 2a, the DPA in FIG. 1 is based on stub-loaded transformers which work as OMNs of the two paths, as mentioned above. Two passbands are realized by multiple TZs produced by shunted T junctions (not shown in FIG. 1), resulting in wide band and compact OMNs. Meanwhile, its impact on impedance transformation is analyzed for the first time after disassembling the T junction. The input impedance of an OMN can satisfy the requirement of load-pull simulation with the help of its T junction(s).

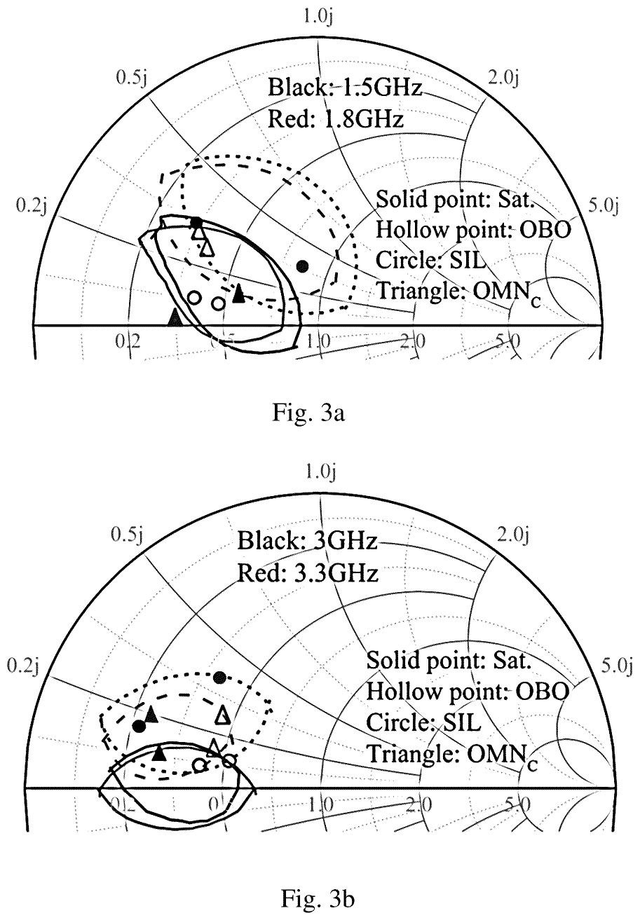

Next, the load-pull simulation will be briefly described. In one embodiment, f_{U} is selected to be about one octave of f_{L}. Since they are far apart, it is necessary to carry out the load-pull simulation to give contours of high efficiency to guide in the design of OMN_{C/P} [24], as shown in FIGS. 3a-3b. The load-pull results and features can be summarized as: (1) variations in the real part is larger than that of the imaginary part; (2) variations in the real part at OBO and saturation are similar; (3) high-efficiency regions at f_{L} is more inductive, and is larger than that at f_{U}; and (4) The region at OBO is more inductive than at saturation.

As a summary to the above discussions, efficiency has a higher tolerance to variation of the real parts whether it is at OBO or at saturation. It is however more sensitive to changes of the imaginary parts with inductive values preferable, especially at OBO and for f_{L}. Input impedance of the OMN_{C/P} is desirable to be as close as possible to the high-efficiency region shown in FIGS. 3a-3b. It will be a huge challenge to the design of OMN_{C/P} for the DPA in FIG. 1 because all above requirements should be met and over two wide frequency bands.

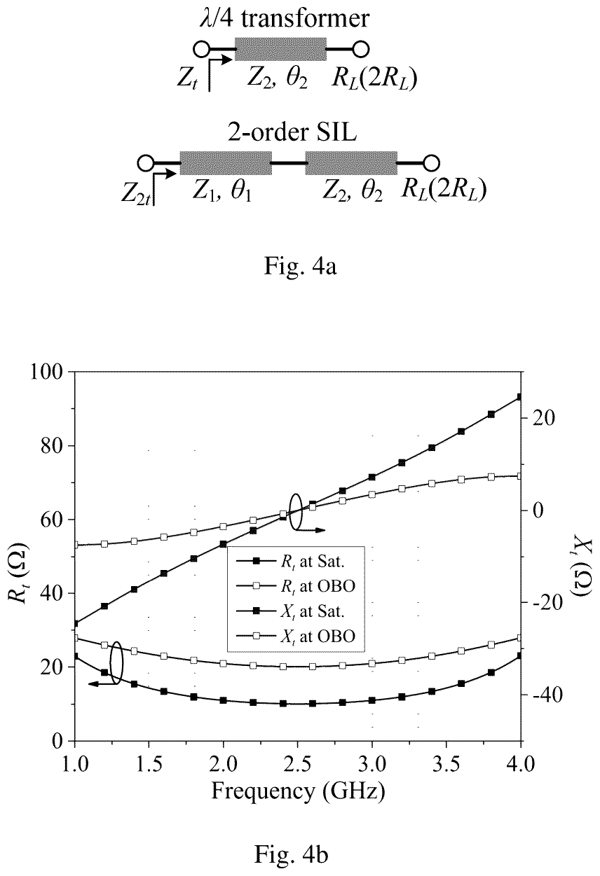

In the following section, SIL and OMN_{C} will be discussed with a comparison between the two. A λ/4 impedance transformer can be considered as all-pass and are widely used as OMNs in wideband DPA designs, as shown in FIG. 4a. Its input impedance Zₜ=Rₜ+jXₜ can be expressed as

$${R}_{t} + {jX}_{t} = {Z}_{2} \frac{{R}_{L} ( 2 {R}_{L} ) + {jZ}_{2} tan {θ}_{2}}{{Z}_{2} + {jR}_{L} ( 2 {R}_{L} ) tan {θ}_{2}} \qquad ( 1 )$$

The real and imaginary parts of both sides of the equation are identical, resulting in

$$tan {θ}_{2} = \frac{( {R}_{t} - {R}_{L} ( 2 {R}_{L} ) ) {Z}_{2}}{{X}_{t} \cdot {R}_{L} ( 2 {R}_{L} )} = \frac{{X}_{t} {Z}_{2}}{{Z}_{2}^{2} - {R}_{t} \cdot {R}_{L} ( 2 {R}_{L} )} \qquad ( 2 )$$

It is worth noting that eqns. (1) and (2) refer to two cases where R_{L} and 2R_{L} represent OBO and saturation states, respectively. According to eqn. (2), the condition for real-to-real conversion to hold true is that θ₂=90° at f₀. However, θ₂<90° for f_{L}, resulting in Xₜ<0, which is corroborated by simulation as shown in FIG. 4b. Similarly, Xₜ>0 for f_{U} but its value at saturation is larger than at OBO. In many aspects, Xₜ does not meet the load-pull requirement although the variation of Rₜ is smooth, and thus a sole λ/4 transformer is not feasible. Cascading cannot address all these issues either.

For a 2-order SIL shown in FIG. 4a, its input impedance is named as Z₂ₜ and is given by

$${Z}_{2 t} = {Z}_{1} \frac{{Z}_{t} + {jZ}_{1} tan {θ}_{1}}{{Z}_{1} + {jZ}_{t} tan {θ}_{1}} \qquad ( 3 )$$

The imaginary part can be calculated as

$${X}_{2 t} = {Z}_{1} \frac{tan {θ}_{1} ( {Z}_{1}^{2} - {R}_{t}^{2} - {X}_{t}^{2} ) + {Z}_{1} {X}_{t} ( 1 - {tan}^{2} {θ}_{1} )}{{( {Z}_{1} - {X}_{t} tan {θ}_{1} )}^{2} + {( {R}_{t} tan {θ}_{1} )}^{2}} \qquad ( 4 )$$

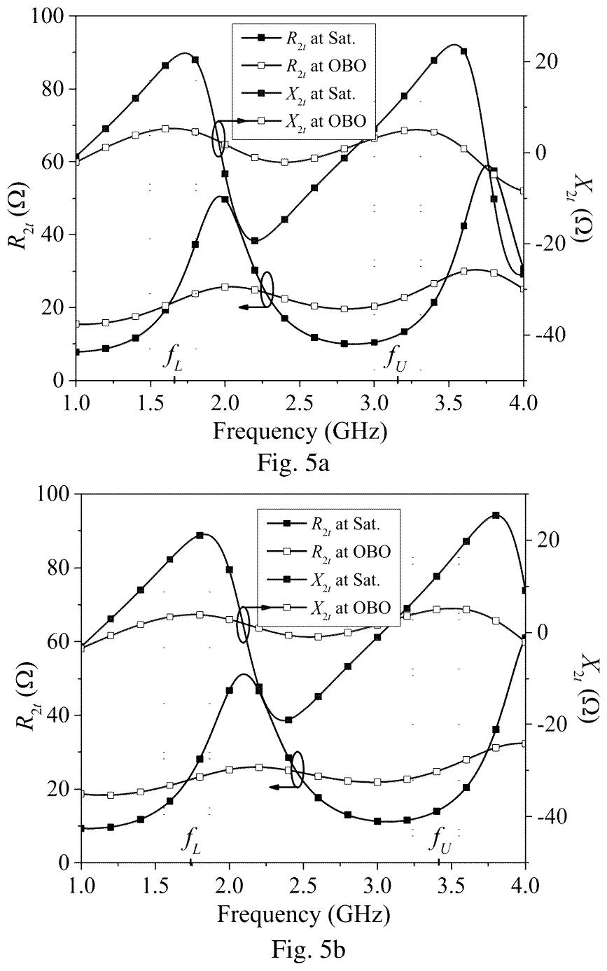

In order to increase inductivity at f_{L}, θ₁ is selected to be slightly smaller than 90° at f_{L} and Zₜ is designed to be Zₜ²≈Rₜ²+Xₜ². It can be seen that the first term in the numerator is small while the second term is a large positive value due to Xₜ<0 at f_{L}, resulting in an inductive X₂ₜ. Meanwhile, this design also realizes a positive X₂ₜ at f_{U} due to θ₁≈180° and Xₜ>0 at f_{U}. FIG. 5a verifies this where θ₁ is 84° at f_{L}. The frequency ratio (f_{U}/f_{L}) can be adjusted by changing Z₁/Z₂ and θ₁, as shown in FIG. 5b. Compared with FIG. 4b, the inductivity of X₂ₜ significantly increases at OBO and saturation for f_{L}. However, X₂ₜ at OBO is much smaller than that at saturation, which run counter to the load-pull results, while R₂ₜ suffers from large fluctuation. Z₂ₜ are denoted as shown in FIGS. 3a-3b, where results deviate from the targeted region, resulting in performance deterioration. Furthermore, the SIL occupies a large size and doesn't have frequency selectivity.

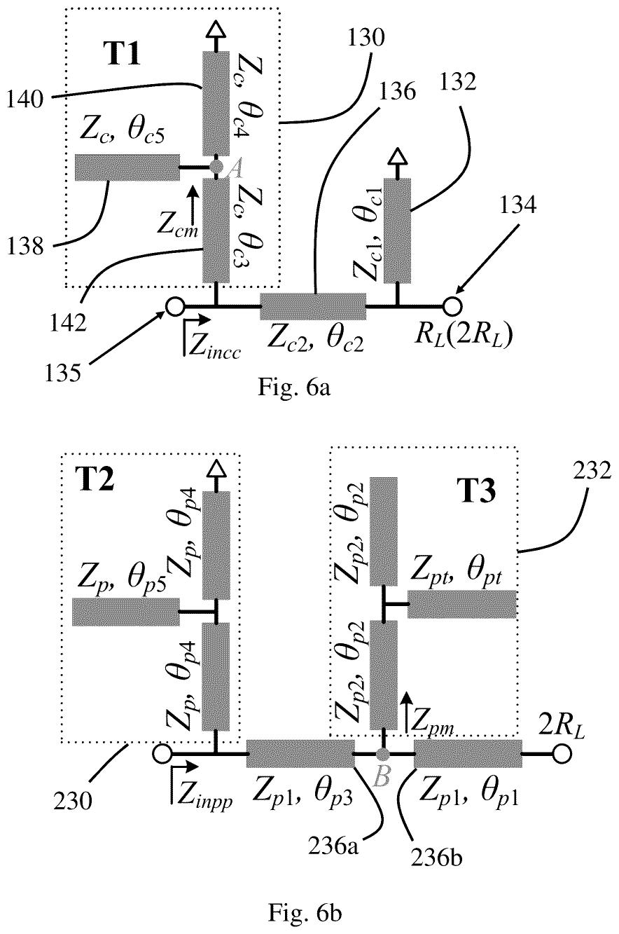

It is therefore clear that the SIL is not suitable for a dual-band DPA as shown in FIG. 1. Instead, T- or π-type transformers are commonly used as OMNs in dual-band DPA designs. FIG. 6a shows an OMN_{C} according to one embodiment of the invention, which could be used for the OMN_{C} 24 in FIG. 1. The OMN_{C} is comprised of two shunted short-circuit stub elements 130, 132. The shunted short-circuit stub element 132 is in the form of a single short-ended shunt stub, and is placed beside an output 134 of the OMN_{C} to create a TZ to split the lower and upper bands. On the other hand, the shunted short-circuit stub element 130 is a shunted T junction (T1) which is placed close to the drain of the carrier device (e.g., a main power amplification device, and not shown in FIG. 6a) and can also contribute to another TZ. As shown in FIG. 6a, the shunted short-circuit stub element 130 is connected by a λ/4 transformer 136 to the shunted short-circuit stub element 132. Within the shunted short-circuit stub element 130, there are three elements that form the T structure, including an open-ended stub 138, a short-ended stub 140, and a short-ended stub 142. The short-ended stub 140 at its one end is biased, and at its other end is connected, at a common node A, to both an end of the open-ended stub 138 and an end of the short-ended stub 142. Another end of the short-ended stub 142 is connected to the input 135 of the OMN_{C} and also to the λ/4 transformer 136.

It is worth noting that shunted stubs not only generate TZs but also perform impedance conversion. The OMN_{C} in FIG. 6a can be analyzed using transmission matrix and the corresponding parameter synthesis, the expression will be cumbersome and will be difficult to explore the effects of each part on impedance conversion, so another method is required. In order to illustrate the mechanism of the OMN_{C}, i.e., how to convert the terminal resistance R_{L} (2R_{L}) to the desired drain impedance, the OMN_{C} will be disassembled step by step with quantitative analysis, that will be verified through simulation. This process of analysis will start from the termination and end at the drain. A shunted short-circuit stub is first placed at the terminal, where its length is selected to be θ_{c1}≈λ/2 at f₀. The input impedance Zᵢ can then be expressed as Zᵢ=R_{L}(2R_{L})//jZ_{c1} tan θ_{c1}, while the real and imaginary parts are given as

$${R}_{i} = \frac{{( {Z}_{c 1} tan {θ}_{c 1} )}^{2} \cdot {R}_{L} ( 2 {R}_{L} )}{{( {R}_{L} ( 2 {R}_{L} ) )}^{2} + {( {Z}_{c 1} tan {θ}_{c 1} )}^{2}} = \frac{{R}_{L} ( 2 {R}_{L} )}{{( \frac{{R}_{L} ( 2 {R}_{L} )}{{Z}_{c 1} tan {θ}_{c 1}} )}^{2} + 1} < {R}_{L} ( 2 {R}_{L} ) \qquad ( 5 )$$

$${X}_{i} = \frac{{Z}_{c 1} tan {θ}_{c 1}}{{( \frac{{Z}_{c 1} tan {θ}_{c 1}}{{R}_{L} ( 2 {R}_{L} )} )}^{2} + 1} \qquad ( 6 )$$

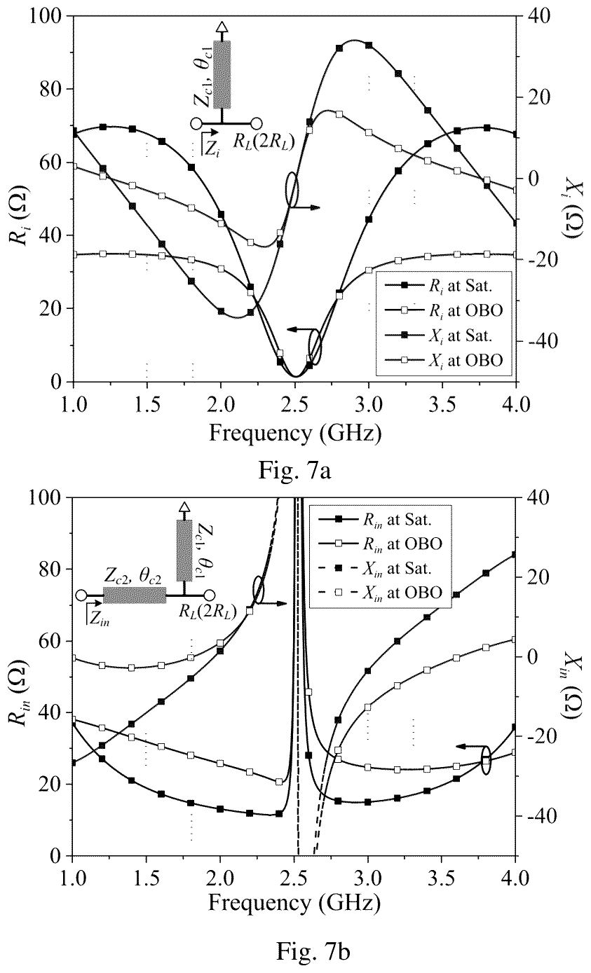

Observing eqn. (5), the terminal resistance can be converted to a smaller Rᵢ by the shunted stub, while Rᵢ at saturation is larger than that at OBO (R_{i_sat}>R_{i_OBO}) due to R_{L}(2R_{L})<<|Z_{c1} tan θ_{c1}| for f_{L} and f_{U}. According to eqn. (6), Xᵢ at OBO is more inductive than at saturation for f_{L}, but they are all negative (0>X_{i_OBO}>X_{i_sat}). For f_{U}, Xᵢ at OBO is smaller although they are positive (X_{i_sat}>X_{i_OBO}>0), as shown in FIG. 7a. Furthermore, whether Rᵢ or Xᵢ, they both suffer from large fluctuation.

Despite the verification of impedance conversion using a shunted stub, Zᵢ is still far away from the designated high-efficiency region. Secondly, a section of transmission line connects to the shunted stub that further increases conversion ratio, as shown in the inset of FIG. 7b. The input impedance Zᵢₙ can be given as

$${Z}_{in} = {Z}_{c 2} \frac{{R}_{i} + j ( {Z}_{c 2} tan {θ}_{c 2} + {X}_{i} )}{( {Z}_{c 2} - {X}_{j} tan {θ}_{c 2} ) + j {R}_{i} tan {θ}_{c 2}} \qquad ( 7 )$$

$${R}_{in} = \frac{{R}_{i} {Z}_{c 2}^{2} ( 1 + {tan}^{2} {θ}_{c 2} )}{{( {Z}_{c 2} - {X}_{i} tan {θ}_{c 2} )}^{2} + {( {R}_{i} tan {θ}_{c 2} )}^{2}}$$

$${X}_{in} = \frac{{X}_{i} {Z}_{c 2}^{2} ( 1 - {tan}^{2} {θ}_{c 2} ) + tan {θ}_{c 2} ( {Z}_{c 2}^{2} - {R}_{i}^{2} - {X}_{i}^{2} )}{{( {Z}_{c 2} - {X}_{i} tan {θ}_{c 2} )}^{2} + {( {R}_{i} tan {θ}_{c 2} )}^{2}}$$

Since Z_{c2} and θ_{c2} do not change for the two states so θ_{c2} is selected to be 45°<θ_{c2}<90° at f_{L} in this design. Therefore, 0>tan θ_{c2}X_{i_OBO}>tan θ_{c2}X_{i_sat} at f_{L} and f_{U}, resulting in R_{in_sat}<R_{in_OBO}. The fluctuation of Rᵢₙ is also significantly reduced except around f₀ because the denominator and numerator are second and first powers of Rᵢ, respectively. The simulation results in FIG. 7b verify this, however, X_{in_sat} shows a large capacitance at f_{L} and X_{in_sat} is still larger than X_{in_OBO} at f_{U}, which are still against the load-pull requirements.

In order to solve these problems, T1 is placed before the line (Z_{c2}, θ_{c2}), which is also used as the drain bias in this design. The open-ended stub of θ_{c5} is first assumed to have negligible effects to simplify the analysis. After adding the short-ended stub of θ_{c34} (θ_{c34}=θ_{c3}+θ_{c4}), the input impedance of the whole OMN_{C} can be calculate as Z_{inc}=Zᵢₙ//jZ_{c} tan θ_{c34}. The performance of Xᵢₙ does not yet satisfy the requirements and thus X_{inc} will be the next main focus.

$${X}_{inc} = \frac{{Z}_{c} tan {θ}_{c 34} ( {R}_{in}^{2} + {X}_{in}^{2} + {X}_{in} {Z}_{c} tan {θ}_{c 34} )}{{R}_{in}^{2} + {( {X}_{in} + {Z}_{c} tan {θ}_{c 34} )}^{2}} \qquad ( 8 )$$

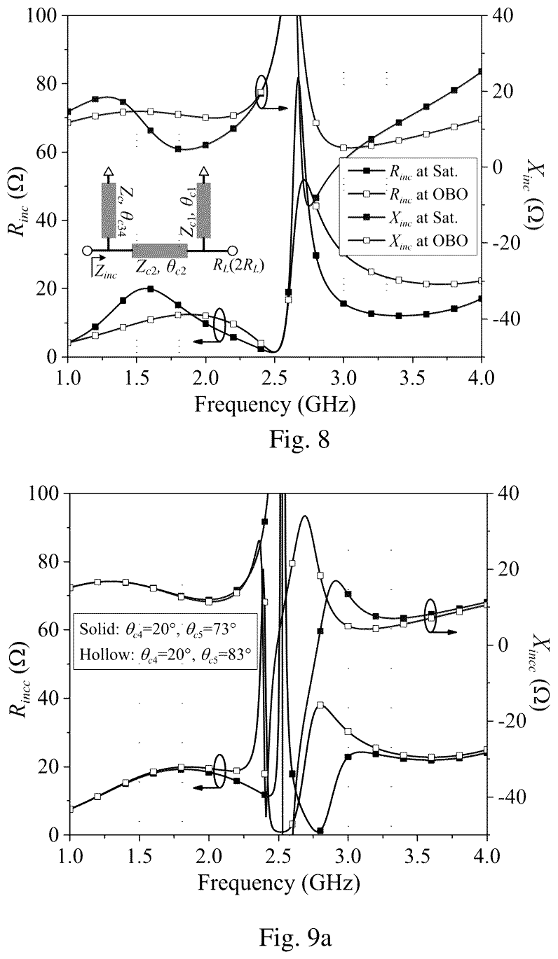

θ_{c34} is selected to be very small, i.e., θ_{c34}<900 at f_{U} which can increase the inductivity of X_{inc} [25]. Furthermore, the difference between X_{inc_sat} and X_{inc_OBO} at f_{U} reduces due to R_{in_sat}<R_{in_OBO} and X_{in_sat}>X_{in_OBO}, as shown in FIG. 8. So far, the input impedance of OMN_{C} gradually approaches the design target although it is still not ideal. The variation of design parameters will simultaneously affect the input impedances at the two passbands which highlights the difficulty of further optimization of performance.

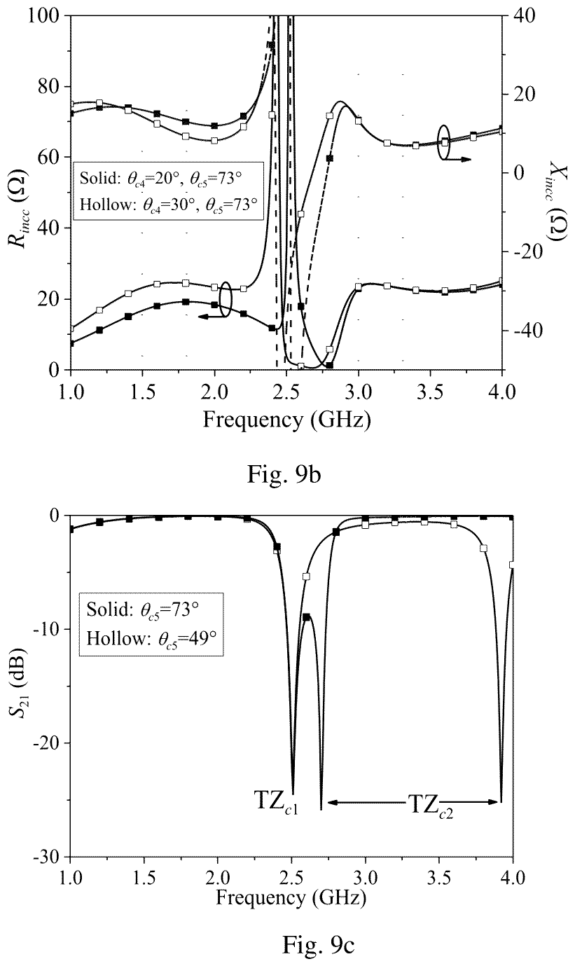

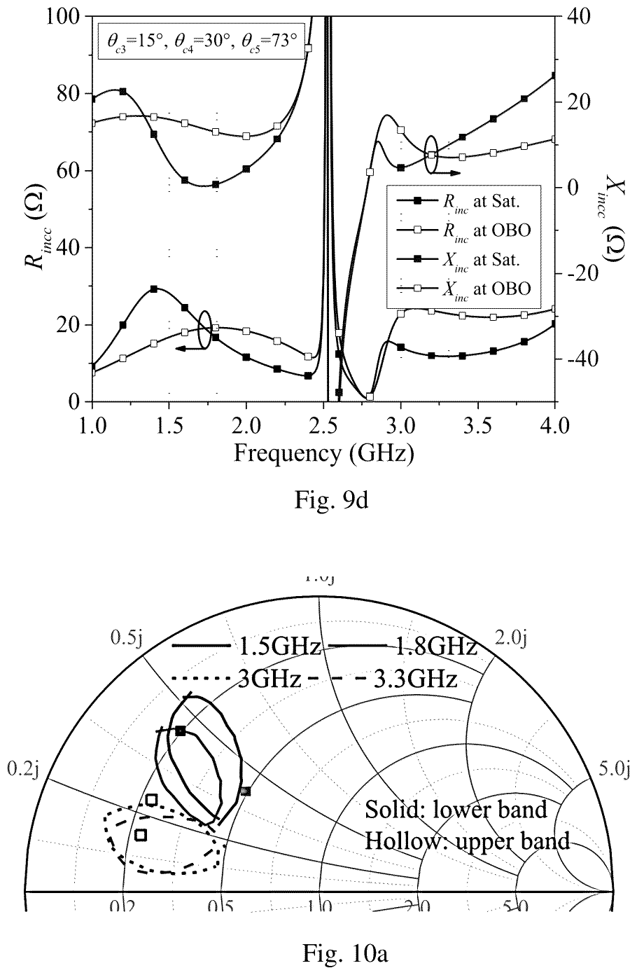

Introducing an open stub of length θ_{c5} aims to quasi-independently control the input impedance at f_{L} and f_{U} respectively. Z_{cm}=jZ_{c} tan θ_{c4}//(−jZ_{c} cot θ_{c5}) and cot θ_{c5} will be much larger than tan θ_{c4} if θ_{c5} is selected to be slightly smaller than 450 at f_{L} because θ_{c4} is very small. Therefore, the variation of θ_{c5} has only a slight influence on Z_{incc} at f_{L}, as shown in FIG. 9a. On the other hand, point ‘A’ in FIG. 6a will be a virtual ground at f_{U}, resulting in a transparent θ_{c4}. Therefore, Z_{incc} at f_{U} is almost immune to θ_{c4}, as shown in FIG. 9b.

For the OMN_{C} without the open stub θ_{c5}, there is only one TZ (TZ_{c1}) between f_{L} and f_{U} created by the short-ended stub θ_{c1}. Another TZ (TZ_{c2}) locates at high frequency produced by the small short-ended stub θ_{c34}. It is interesting that the stub θ_{c5} not only affects the input impedance but can also adjust TZ_{c2}, as shown in FIG. 9c. The longer the open stub θ_{c5} is, the lower the TZ_{c2} will be, while the selectivity of the two passbands is increased. Furthermore, the frequency of TZ_{c2} can be controlled by point ‘A’ because it is controlled by the loading position. FIG. 9d shows optimized Z_{incc} at OBO and saturation where the values at 1.5, 1.8, 3 and 3.3 GHz are labelled in FIG. 3. Compared with Z_{2t_sat} and Z_{2t_OBO}, they are in or very close to the high-efficiency regions, which means the OMN_{C} in FIG. 6a is much more attractive than SIL in terms of dual-band impedance conversion. Furthermore, the OMN_{C} has two TZs which fortuitously can be integrated with the drain bias, and is suitable for the DPA in FIG. 1.

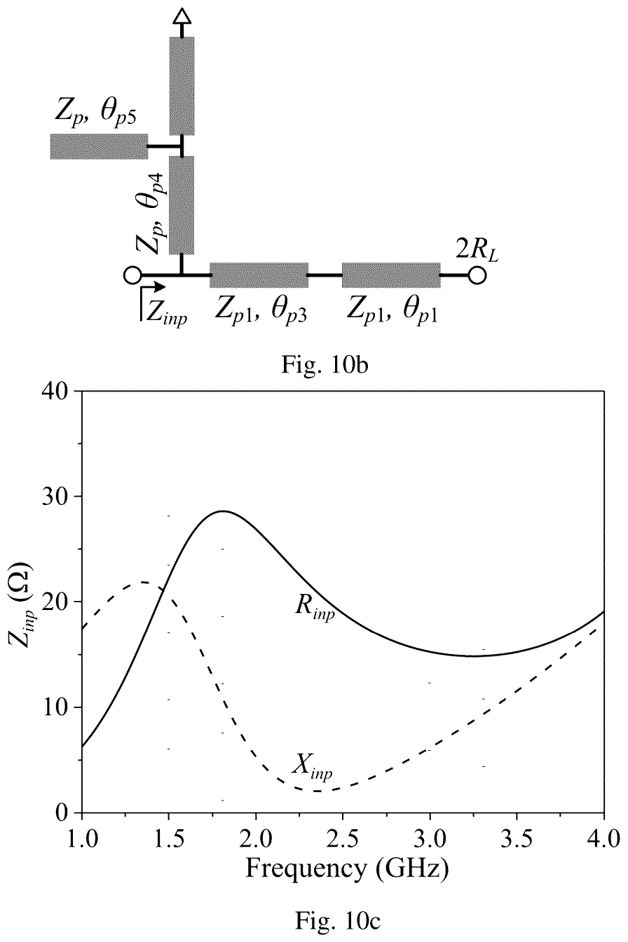

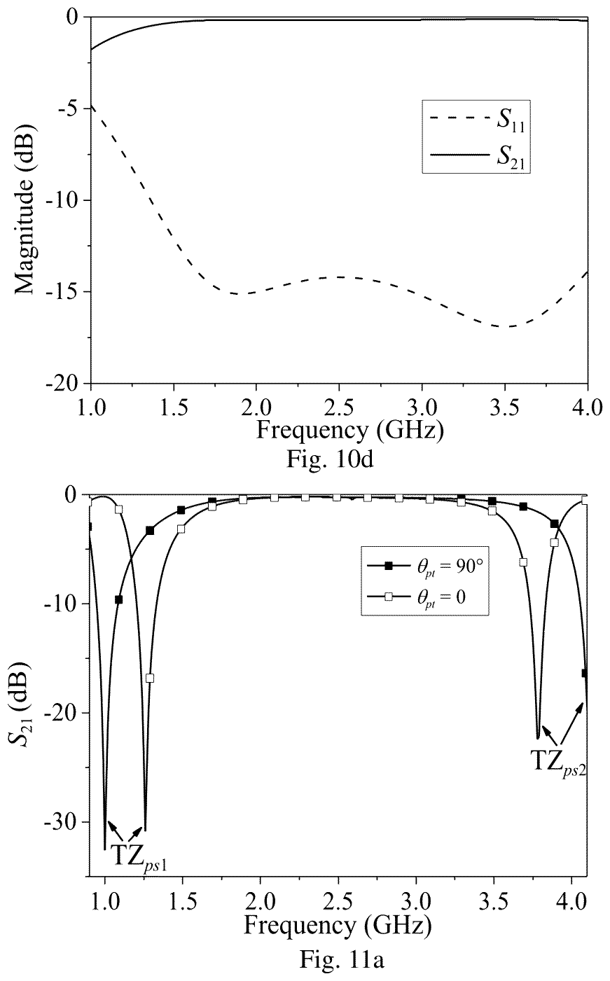

Having described the design principle of the OMN_{C}, the description now comes to the design principle of the OMN_{P}. In terms of impedance conversion, the design of the OMN_{P} is relatively easy due to its requirement at saturation state only. This can be realized using a λ/4 transformer with results similar to that in FIG. 4b. Although large-ratio and smooth conversion can be realized in resistance, the reactance is negative at f_{L}, which does not conform to the requirement in FIG. 10a. Thus, the OMN_{P} as shown in FIG. 6b contains two T junction structures respectively as two shunted short-circuit stub elements 230, 232. The shunted short-circuit stub element 230 is a shunted T junction (T2) which is connected, at an input 235 of the OMN_{P}, to a drain of the peaking device (e.g., an auxiliary power amplification device, and not shown in FIG. 6b), and serves as a bias for the peaking drain. The shunted short-circuit stub element 230 is connected to and located before a λ/4 transformer. On the other hand, the shunted short-circuit stub element 232 is another shunted T junction (T3) which is connected to point “B” between two stubs 236a, 236b of the λ/4 transformer. The shunted short-circuit stub elements 230, 232 have similar “T” structures which are also similar to that of T1 as described above and shown in FIG. 6a. Therefore, the structures and internal elements of the T junctions T2 and T3 will not be described again here for the sake of brevity.

The small T junction T2 (i.e., the shunted short-circuit stub element 230) is a modification of a short-ended stub element, which can increase inductivity and has been verified above. FIG. 10b shows T2 and the λ/4 transformer in FIG. 6b alone. The impedance conversion result of FIG. 10b is shown in FIG. 10c, where Z₁, has approached the high-efficiency circle after the addition of T2.

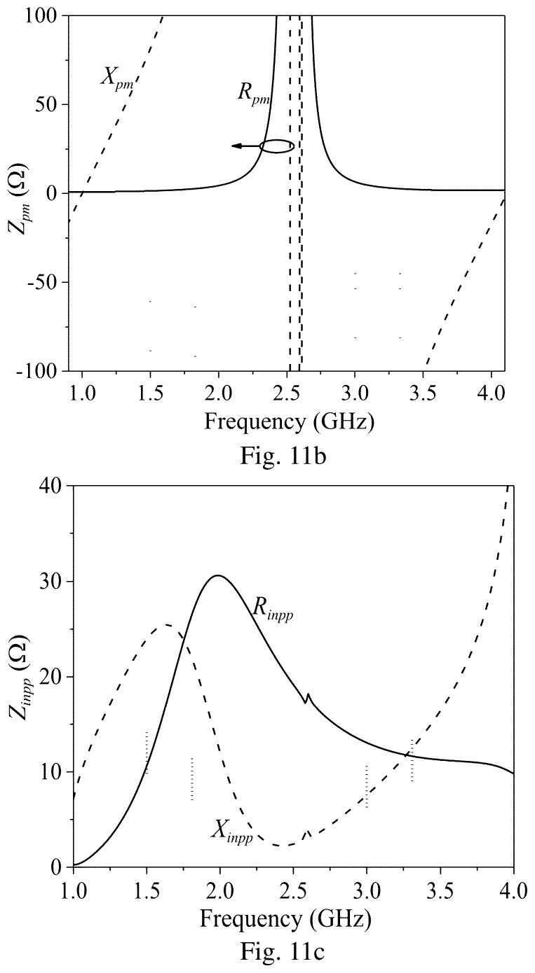

The function of short stub θₚ₅ is dissimilar to the stub θ_{c5} and it mainly serves its purpose at OBO rather than at saturation, which will be discussed later. Therefore, T2 will not contribute to TZs in forming dual passbands at saturation, and both of θₚ₄ and θₚ₅ are selected to be very small, as shown in FIG. 10d. As mentioned above, the OMN_{C} contributed to two TZs at around f₀ but are insufficient to construct two passbands. Besides impedance conversion, the OMN_{P} is also required to generate more TZs and thus another T junction T3 is attached to the λ/4 transformer, which can generate TZs at edge frequencies (TZ_{LE} and TZ_{UE} in FIG. 2b). The position of the TZs is determined by θₚ₂ if without the stub θₚₜ, and f_{UE} would be triple the frequency of f_{LE}. f_{LE} and f_{UE} are selected to be about 1 and 4 GHz in one example and thus the stub θₚₜ is used here to slightly tune their positions, as shown in FIG. 11a. The input impedance Zₚₘ of T3 is also plotted in FIG. 11b and shows large-value and therefore has a negligible effect on the impedance Zᵢₙ. Thus, the loading position of T3 (point ‘B’ in FIG. 6b) is flexible. FIG. 11c shows the Zᵢₙₚₚ of the whole OMN_{P} which is similar to that in FIG. 10c. Zᵢₙₚₚ at f_{L} and f_{U} are labelled in FIG. 10a and it can be seen that they all approach the high-efficiency region. OMN_{C} and OMN_{P} each generate two TZs at saturation and thus their combination can form two passbands as shown in FIG. 11d. It can be noted that bandwidths of the two bands are broad, but the DPA's operating bandwidth is limited by the input impedance of the OMN which must veer towards the required load-pull results.

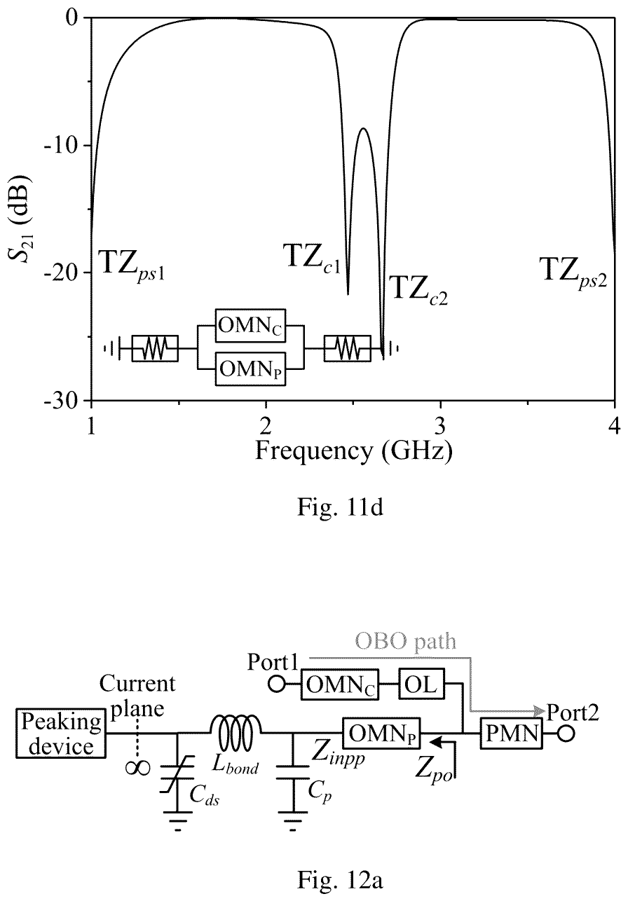

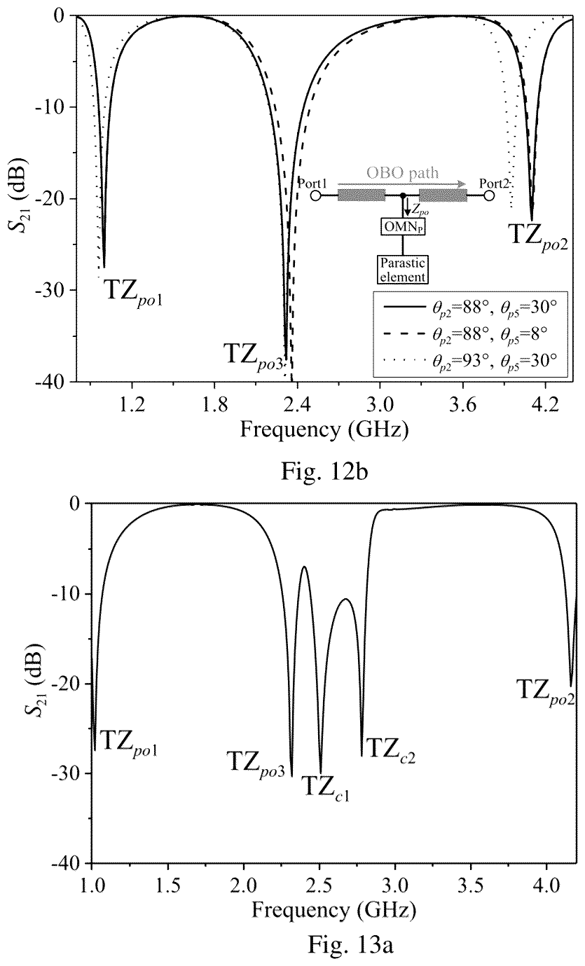

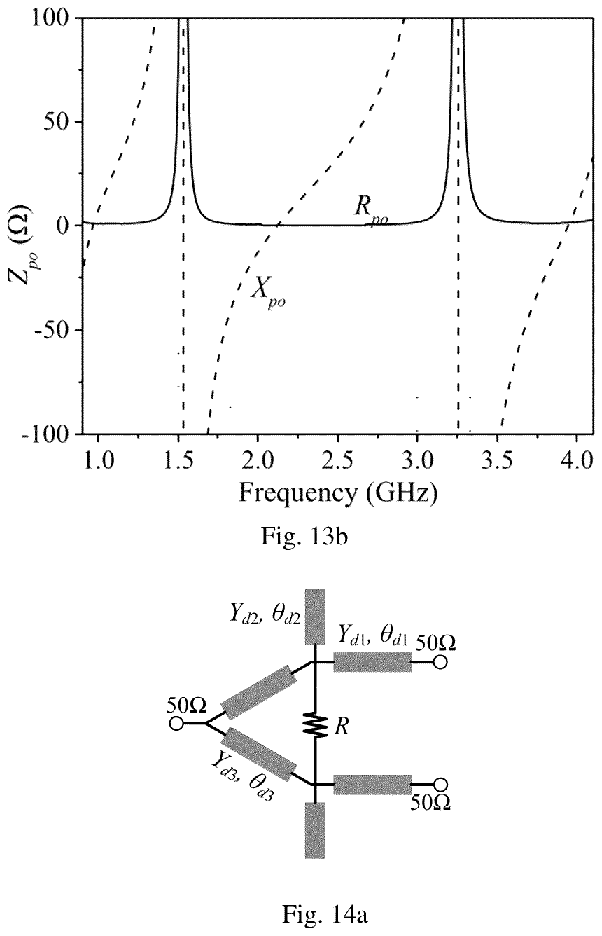

A dual-passband characteristic of the DPA has been fulfilled by combining the OMN_{C} and OMN_{P} at saturation. This is also required at OBO on the basis of the changed peaking path. FIG. 12a shows a schematic diagram of the OMNs where the terminal impedance at the current plane is infinite because the peaking device is off, but the peaking device still connects with the OMN_{P} and thus some parasitic elements cannot be ignored where L_{bond} and Cₚ denote the bonding inductance and pad capacitance. Therefore, OMN_{P} together with these parasitic elements is in shunt with the OBO path which is different from the configuration at saturation. In order to observe the transmission characteristic of the peaking path at OBO, the OMN_{C} and PMN are simplified, as shown in FIG. 12b. The peaking path can generate three TZs, which include TZₚₒ₁ and TZₚₒ₂ that are controlled by T3 and point ‘B’ in FIG. 6b. TZₚₒ₃ is mainly controlled by T2. Since θₚ₄ participates in the design of Zᵢₙₚ and the parasitic elements are determined by the transistor model, and thus the position of TZₚₒ₃ can be adjusted by only changing Ops. The combination between OMN_{C} and OMN_{P} at OBO will generate a total of five TZs after adding the two TZs contributed by OMN_{C}, as shown in FIG. 13a. It is slightly different from the result at saturation but the dual-passband characteristic is still maintained.

The impact from the peaking path on the carrier path is expected to be minimal at OBO in this DPA's design. Zₚₒ should be large value to achieve this goal. FIG. 13b shows that Zₚₒ≈0 at f_{TZpol-3} and it presents large value between the three frequency points. This can ensure that the impedance conversion of the OMN_{C} at OBO while being unaffected by the shunt peaking path.

The circuit design of the DPA will now be described. The DPA is designed and fabricated using two Cree CGH40010F GaN HEMT devices with gate biases of Class AB mode (−3V) and Class C mode (−5.8V) for the carrier and peaking paths, respectively. The drain supply voltages of both the carrier and peaking devices are symmetrical at 28V.

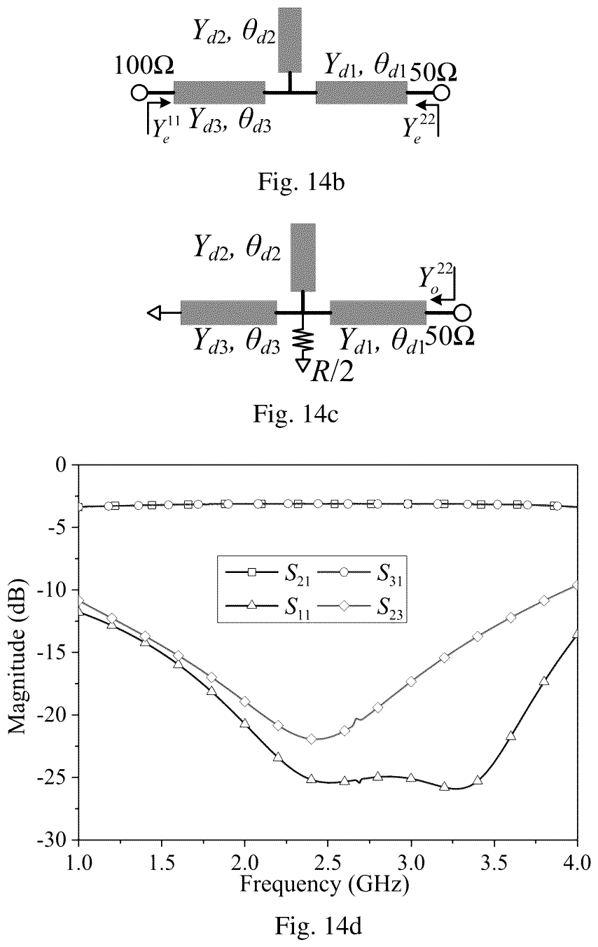

A dual-band 3-dB power divider or couplers can be used as an input power splitter but its bandwidth is insufficient for the dual-passband DPA. A compact stub-loaded power divider is used in one implementation, as shown in FIG. 14a, where Y_{di} and θ_{di} (i=1, 2, 3) denote the characteristic admittance and electrical length of the transmission lines, respectively. The even- and odd-mode sub-circuits are presented in FIG. 14b and FIG. 14c. The input admittance Yₑ¹¹, Yₑ²² and Yₒ²² can be calculated when Y₀ is 1/50 S.

$${Y}_{e}^{11 / 22} = {Y}_{d 3 / 1} \frac{{Y}_{L 1} + {jY}_{d 3 / 1} tan {θ}_{d 3 / 1}}{{Y}_{d 3 / 1} + {jY}_{L 1} tan {θ}_{d 3 / 1}} \qquad ( 9 )$$

$${Y}_{L 1} = {Y}_{d 1 / 3} \frac{{Y}_{0} + {jY}_{d 3 / 1} tan {θ}_{d 3 / 1}}{{Y}_{d 3 / 1} + {jY}_{0} tan {θ}_{d 3 / 1}} + {jY}_{d 2} tan {θ}_{d 2}$$

$${Y}_{o}^{22} = {Y}_{d 1} \frac{{Y}_{L 2} + {jY}_{d 1} tan {θ}_{d 1}}{{Y}_{d 1} + {jY}_{L 2} tan {θ}_{d 1}}$$

$${Y}_{L 2} = \frac{{jY}_{d 3}}{tan {θ}_{d 3}} + {jY}_{d 2} tan {θ}_{d 2} + \frac{2}{R}$$

$$\begin{matrix}{S}_{11} = {S}_{11}^{e} = \frac{0.5 {Y}_{0} - {Y}_{e}^{11}}{0.5 {Y}_{0} + {Y}_{e}^{11}} & {S}_{22}^{e} = \frac{{Y}_{0} - {Y}_{e}^{22}}{{Y}_{0} + {Y}_{e}^{22}} = 0\end{matrix} \qquad ( 10 )$$

$$\begin{matrix}{S}_{22}^{o} = \frac{{Y}_{0} - {Y}_{22}^{o}}{{Y}_{0} + {Y}_{22}^{o}} & 2 {S}_{23} = {S}_{22}^{e} - {S}_{22}^{o}\end{matrix} \qquad ( 11 )$$

It can be seen that S_{2/31} is only related to the even-mode bisection according to the relationship |S₁₁|²+|S_{2/31}|²=0. The isolation between the two output ports S₂₃ is determined by the resistor value R. The simulated results shown in FIG. 14d gives wideband power division with small loss. The capacitive loaded stub θ_{d2}, θ_{d1} is only 25° and much smaller than λ/4, giving rise to a very compact design.

In order to clarify the circuit design of a dual-passband DPA, its design procedure is summarized as follows:
1) Load-pull simulation: Select edge frequencies of the two passbands and contour the high-efficiency regions. Summarize the feature of the load-pull impedance.
2) OMN_{C} design: A short-ended stub is first placed near to the terminal with θ_{c1}≈λ/2 at f₀ for generating TZ_{c1} and impedance conversion. θ_{c2} is slight smaller than 900 at f_{L} to increase conversion ratio and reduce impedance fluctuation. θ_{c34} is designed to be small to increase the inductivity of the imaginary part. The stub θ_{c5} is slightly smaller than 450 at f_{L} for quasi-independently controlling the input impedance, while it can lower TZ_{c2} to improve selectivity, which can be adjusted by changing the position of ‘point A’.
3) OMN_{P} design: For saturation, the impedance conversion is mainly realized using a λ/4 transformer θₚ₁₃. Short bias stub θₚ₄ increases inductivity. θₚ₂ and θₚₜ determine the position of TZ_{ps1/2}, which has negligible effect on impedance conversion. For OBO, the loading position of point ‘B’ can be tuned for controlling the position of TZₚₒ₁₋₃ at OBO while small θₚ₅ is used to independently control TZₚₒ₃.
4) IMN and power divider: Multi-section stepped-impedance lines are used to design broadband IMNs. A PCN is added to the peaking path to compensate for the phase difference between the two paths. The compact power divider is designed based on eqns. (9)-(11).
5) Frequency ratio and bandwidth limitations: Frequency ratio of the two passbands is restricted by the bandwidth of SIL and positions of TZs. The larger the ratio, the more difficult is the design. The operating bandwidths of the DPA mainly depends on design of the OMNs, where their input impedances need to match the required load-pull impedances. Although the ranges of most design parameters are given, further software optimization is beneficial.

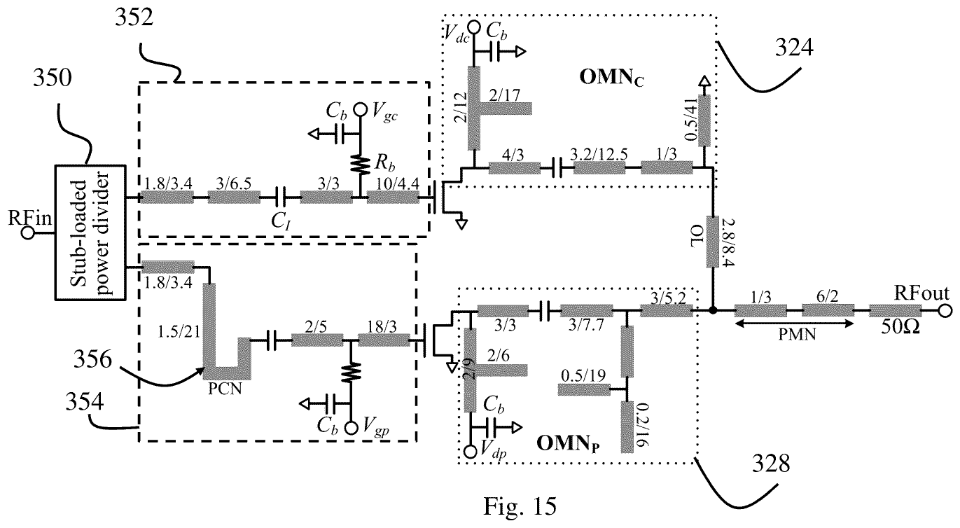

The complete configuration of the dual-passband DPA in one embodiment is shown in FIG. 15, where SMT capacitors are used for DC blocking. One can see that the DPA in FIG. 15 incorporates the OMN_{C} design in FIG. 6a and also the OMN_{P} design in FIG. 6b. In the DPA, input power is split equally and in-phase by a compact wideband power divider 350 which for example may be the power divider shown in FIG. 14a. A main side IMN 352 is connected between the power divider 350 and the main power amplification device 324, and an auxiliary side IMN 354 is connected between the power divider 350 and the auxiliary power amplification device 328. In addition, there is a PCN 356 located in the auxiliary side IMN 354.

Gate and drain bias stubs are short-circuited at the far end via bypass capacitors C_{b} which prevents RF signals from flowing into the DC power supplies. C_{I} and R_{b} are optimized to make sure an unconditional stability. For experimental validation purpose, a sample of the dual-passband DPA is fabricated, which only occupies a compact area of 66×57 mm².

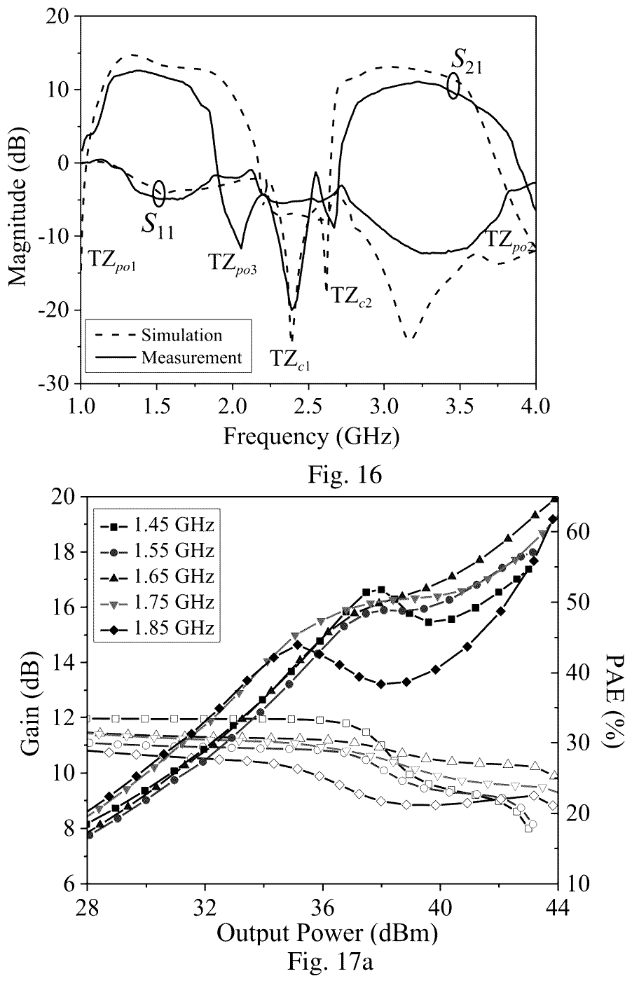

For continuous-wave signal measurement, small-signal performance is measured using the Agilent ENA series network analyzer E5071C. FIG. 16 shows the small-signal performance of the DPA in FIG. 15, which corresponds to FIG. 12a. Multiple TZs form the two passbands where TZₚₒ₁₋₃ and TZ_{c1-2} come from the peaking path at OBO and the carrier path, respectively.

Good agreement can be observed between simulation and measurement, with the discrepancy attributed to parasitic effects from the surface mount components and fabrication tolerances. The measured lower passband is smaller compared with simulation due to the TZₚₒ₃ which is sensitive to the parasitic elements C_{ds}, Cₚ and L_{bond}. Furthermore, TZₚₒ₃ comes from T2 where the lines θₚ₅ (in T2) and θₚₜ (in T3) are placed to be close each other for compact design. However, their mutual coupling affects the position of TZₚₒ₃. Their values differ between simulation model and practical transistor. Return loss in the lower band is not as good as the upper one due to a better S₁₁ at high frequencies for the power divider. The measured maximum small-signal gains are 12.6 and 11.2 dB, respectively, both with −400 MHz 1-dB bandwidths.

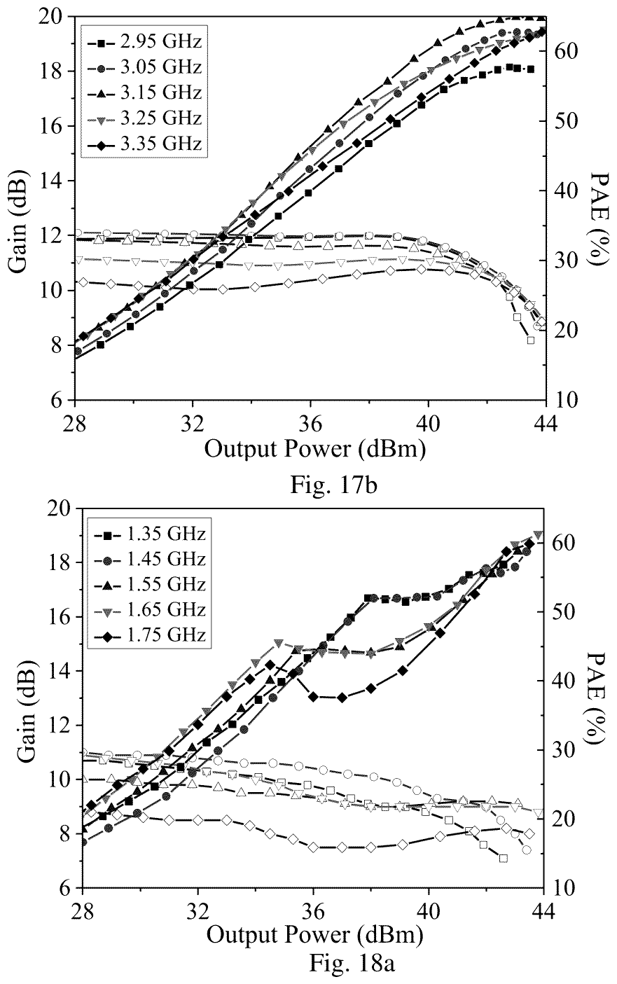

FIG. 17 shows the simulated large-signal response for the lower and upper bands. For the lower band, P1 dB gain changes from 9 to 10.2 dB while saturated output power varies from 42.8 to 44.2 dBm. The 6-dB OBO and saturated PAEs change from 44% (9-dB OBO) to 50% and 55.7% to 65.5%, respectively. For the upper band, the gain changes from 9.4 to 10.4 dB at saturation with an output power variation from 43.4 to 43.9 dBm. The 6-dB OBO and saturated PAEs change from 44.5% to 53.7% and 57.4% to 64.7%, respectively. The OBO efficiency peak is not clear at the high frequency edge, while the peaking device turns on slightly early due to mismatch. This is common in dual-band DPAs [11], [18], with dynamic load-modulation techniques being a potential solution [26].

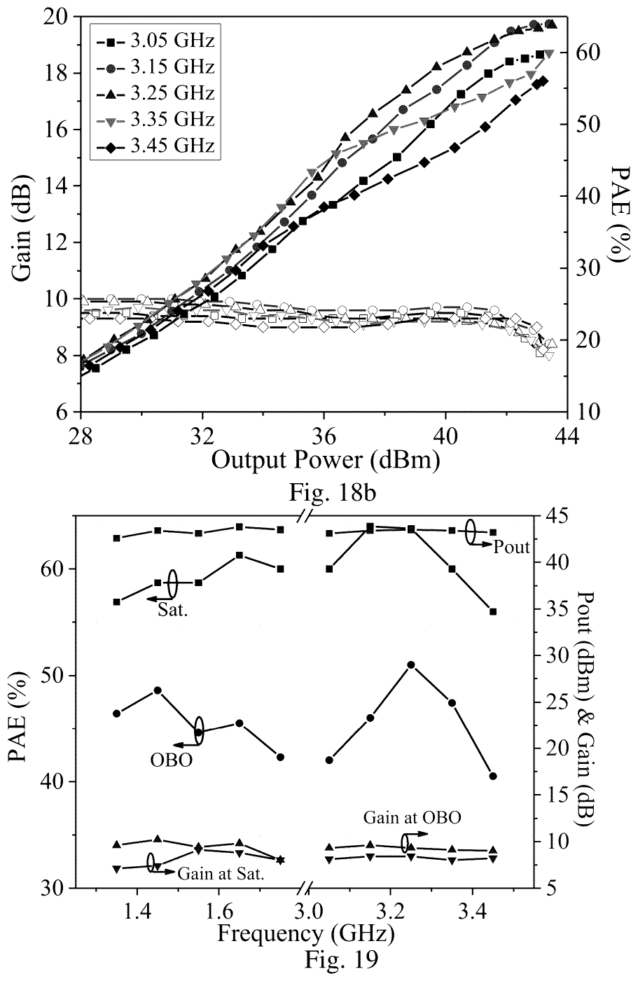

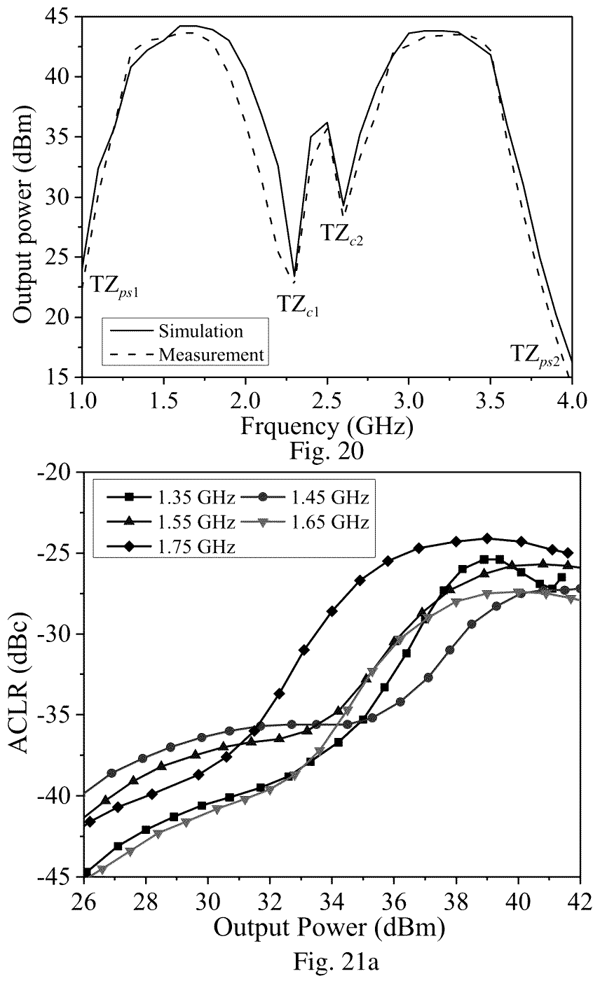

FIG. 18 shows the measured large-signal response for the lower and upper bands. At 1.55 GHz, the PAE is 58.7% at saturation with an output power of 43.1 dBm, and 45.6% at 6-dB OBO. Gain decreases from 9.1 (OBO) to 9.4 dB (saturation). At 3.25 GHz, the DPA achieves a PAE of 63.8% at saturation (43.5 dBm) and 51% at an output power of 37.5 dBm. The gain decreases from 9.4 to 8.4 dB, indicating a small compression. FIG. 19 compares the measured performance versus frequency. For the lower band from 1.35 to 1.75 GHz, the measured P1 dB gain varies from 7.4 to 9.2 dB and with gain compression smaller than 3.5 dB. Measured saturated output power varies from 42.6 to 43.8 dBm with PAE changing from 56.9% to 61.3%, while the 6-dB OBO PAE varies from 42.3% (9-dB OBO) to 48.6%. For the upper band from 3.05 to 3.45 GHz, the gain varies from 9 to 9.6 dB and 8.6 to 9 dB for 6-dB OBO and saturation, respectively. Gain compression is smaller than 2 dB. The 6-dB OBO and saturated PAEs change from 40.5% to 51% and 56% to 64%, respectively. Output power changes from 43.1 to 43.4 dBm at saturation. The dual-band filtering characteristic of the DPA at saturation is shown in FIG. 20, which corresponds to FIG. 11b. FIGS. 16 and 20 verify that the dual-passbands response can be obtained simultaneously at OBO and saturation for the proposed DPA.

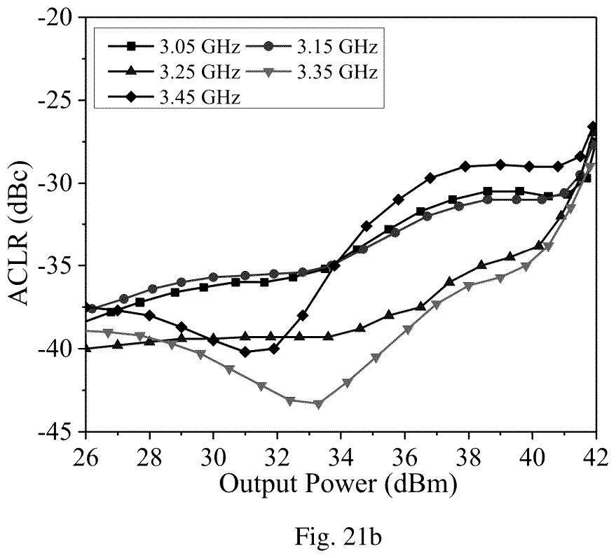

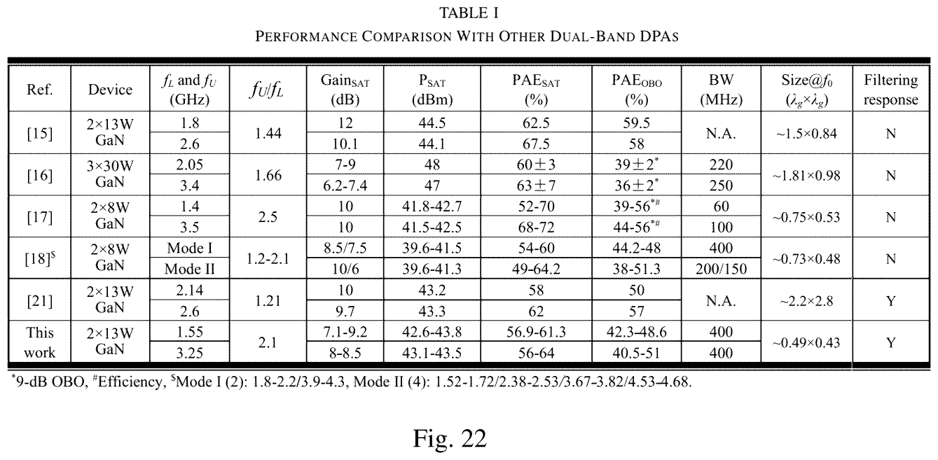

To verify the linearity of the DPA, measurements are performed on the fabricated sample using a Keysight signal generator E4433B and an R&S FSV signal analyzer. A single carrier test signal with PAPR of 6.5 dB at 0.1% probability of complementary cumulative distribution function is generated. Adjacent channel leakage ratio (ACLR) is measured with a 3.84 MHz channel bandwidth. The measured results are shown in FIG. 21 with only one shown due to symmetry of the ACLR. The lower ACLR performance of the proposed DPA is better than −24 dBc in the two passbands.

A performance comparison between the dual-passband DPA and recently published state-of-the-art dual-band DPAs is summarized in Table I. The performance of the DPA is comparable to other designs with the frequency ratio larger than 2. The sum of bandwidth for the two passbands is 800 MHz which is close to the bandwidth of a wideband DPA. In addition, only the dual-band DPA (referred as “this work” in Table 1) and the work in [19] integrates filtering functions, with the latter only operating at two frequency points. Furthermore, the area of the circuit of the DPA is the smallest compared with all listed works. It should be noted that the circuit footprints are not provided by most papers, and so are estimated here by using known SMA connector or transistor dimensions. The proposed DPA has two passbands, wide bandwidths, integrated function and small size. These features make it an ideal candidate for potential small-cell transmitters.

The exemplary embodiments are thus fully described. Although the description referred to particular embodiments, it will be clear to one skilled in the art that the invention may be practiced with variation of these specific details. Hence this invention should not be construed as limited to the embodiments set forth herein.

While the embodiments have been illustrated and described in detail in the drawings and foregoing description, the same is to be considered as illustrative and not restrictive in character, it being understood that only exemplary embodiments have been shown and described and do not limit the scope of the invention in any manner. It can be appreciated that any of the features described herein may be used with any embodiment. The illustrative embodiments are not exclusive of each other or of other embodiments not recited herein. Accordingly, the invention also provides embodiments that comprise combinations of one or more of the illustrative embodiments described above. Modifications and variations of the invention as herein set forth can be made without departing from the spirit and scope thereof, and, therefore, only such limitations should be imposed as are indicated by the appended claims.

It will be appreciated by persons skilled in the art that the expressions “network” or the like are used in the description to refer to a circuit or circuit part, which can be form by any combination of transmission line, transmission line portions, or other active or inactive electronic circuit components. The term “offset line” can also be called an “offset transmission line”. The term “main power amplification device”, “carrier device”, or the like, refers to a “carrier power amplifier” or “carrier amplifier”. The term “auxiliary power amplification device”, “peaking device”, or the like, refers to a “peaking power amplifier” or “peaking amplifier”. Unless otherwise specified, the term “connected”, “engaged”, “coupled with/to”, or the like, may refer to direct or indirect connections, engagement, coupling, etc. The expression “Doherty power amplifier circuit” can be used to refer to a “Doherty power amplifier” or any parts of it.

What is claimed is:

1. A Doherty power amplifier comprising:
a) an input;
b) an output;
c) a main power amplification device connected between the input and the output;
d) an auxiliary power amplification device connected between the input and the output, and arranged in parallel with the main power amplification device;
e) a main side output matching network (OMN) connected between the main power amplification device and the output; and
f) an auxiliary side OMN connected between the auxiliary power amplification device and the output;
wherein the main side and auxiliary side OMNs each comprise a first shunted T junction, the first shunted T junctions facilitating creation of multiple transmission zeros (TZ) as well as impedance conversion.

2. The Doherty power amplifier of claim 1, wherein the first shunted T junction of the main side OMN or the auxiliary side OMN facilitates generation of two TZs in a corresponding one of the main side and auxiliary side OMNs.

3. The Doherty power amplifier of claim 1, wherein the main side OMN further comprises a shunted short-circuit stub, and a λ/4 transformer connected between the first shunted T junction and the shunted short-circuit stub.

4. The Doherty power amplifier of claim 1, wherein the auxiliary side OMN further comprises a second shunted T junction, and a λ/4 transformer at least partially connected between the first and second shunted T junctions.

5. The Doherty power amplifier of claim 1, further comprising a stub-loaded power divider connected between the input, and the main and auxiliary power amplification devices.

6. The Doherty power amplifier of claim 5, further comprising a main side input impedance matching network (IMN) connected between the stub-loaded power divider and the main power amplification device, and an auxiliary side IMN connected between the stub-loaded power divider and the auxiliary power amplification device.

7. The Doherty power amplifier of claim 6, further comprising a phase compensation circuit located in the auxiliary side IMN.

8. The Doherty power amplifier of claim 1, wherein the first shunted T junction is connected to a drain of a corresponding one of the main and auxiliary power amplification devices.

9. The Doherty power amplifier of claim 1, wherein input impedances of the main and auxiliary power amplification devices are complex impedances, and a load impedance of the Doherty power amplifier is a real impedance.
